(19) United States
(12) Patent Application Publication
(10) Pub. No.: US 2026/0006760 A1
(43) Pub. Date: Jan. 1, 2026

(54) DEDICATED PSU AIRFLOW INLET FOR STORAGE ENCLOSURE

(71) Applicant: Seagate Technology LLC, Fremont, CA (US)

(72) Inventors: Lon Matthew STEVENS, Longmont, CO (US); Joseph P. MANES, Longmont, CO (US)

(21) Appl. No.: 19/252,134

(22) Filed: Jun. 27, 2025

Related U.S. Application Data
(60) Provisional application No. 63/666,029, filed on Jun. 28, 2024.

(51) Int. Cl. H05K 7/20

(52) U.S. Cl. CPC H05K 7/20909

(57) ABSTRACT

A device may include an enclosure. The device may include a plurality of storage drives configured along a length of the enclosure from a front of the enclosure to a rear of the enclosure, the enclosure surrounding the plurality of storage drives at least in part. The device may include a duct configured along the length of the enclosure, the duct configured to communicate an airflow from the front of the device to a power supply unit (PSU) located near a rear of the device.

### CROSS-REFERENCE TO RELATED APPLICATION

This application claims priority to U.S. Provisional Application No. 63/666,029, filed on Jun. 28, 2024, and entitled “DEDICATED PSU AIRFLOW INLET FOR STORAGE ENCLOSURE.” The above-referenced application is incorporated herein by reference for all that it discloses and teaches.

### BACKGROUND

A storage device may become overheated without effective cooling mechanisms such as fans. In a conventional storage device, a set of one or more fans pulls and/or pushes a stream of air through (e.g., over, around, etc.) storage drives, power supply units (PSUs), and other hardware components of the storage device that require cooling.

### SUMMARY

This disclosure is directed to a storage device enclosure including a duct configured to direct an airflow to a power supply unit (PSU) of a storage device that is separate from another airflow to one or more other components of the storage device.

In some aspects, the techniques described herein relate to a device, including: an enclosure; a plurality of storage drives configured along a length of the enclosure from a front of the enclosure to a rear of the enclosure, the enclosure surrounding the plurality of storage drives at least in part; and a duct configured along the length of the enclosure, the duct configured to communicate an airflow from the front of the device to a power supply unit (PSU) located near a rear of the device.

In some aspects, the techniques described herein relate to a storage system, including: an enclosure; a plurality of storage drives configured along a length of the enclosure from a front of the enclosure to a rear of the enclosure, the enclosure surrounding the plurality of storage drives at least in part; a duct configured along the length of the enclosure, the duct configured to communicate an airflow from the front of the enclosure to a power supply unit (PSU) located near a rear of the enclosure; a PSU fan unit configured to drive the airflow; and an air expansion cavity configured within the inlet to expand the airflow to a surface of the PSU.

Other systems and methods are also described herein.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. These and various other features and advantages will be apparent from a reading of the following detailed description.

### BRIEF DESCRIPTION OF THE DRAWING

The described technology is best understood from the following Detailed Description describing various implementations read in connection with the accompanying drawing.

FIG. 1 depicts a storage device.

FIG. 2 depicts a storage device with a storage drives section retracted and a top cover removed from an enclosure of the storage device.

FIG. 3 depicts a storage device with a storage drives section removed from an enclosure of the storage device.

FIG. 4 depicts a portion of an example enclosure of a storage device with the plenum and fans that provide the main cooling for the storage devices removed.

FIG. 5 depicts a portion of an example enclosure including PSUs and components that provide the inlet paths to the PSUs.

FIG. 6 depicts a portion of an example enclosure including a duct.

FIG. 7 depicts a portion of an example enclosure including a duct.

FIG. 8 depicts a portion of an example enclosure including a duct with air expansion cavities for effective cooling of a PSU.

FIG. 9 depicts a portion of an example enclosure including a duct for cooling of a PSU.

FIG. 10 depicts a portion of an example enclosure including a duct for cooling of a PSU.

### DETAILED DESCRIPTION

Storage devices may become overheated without effective cooling mechanisms such as fans. In a conventional storage device, a set of one or more fans pulls and/or pushes a common flow of air through (e.g., over, around, etc.) storage drives, power supply units (PSUs), and other hardware components of the storage device that require cooling. However, a single air flow may not adequately cool certain hardware components of the storage device. For example, after the single airflow passes a set of storage drives, cooling the set of storage drives, a PSU located behind the set of storage drives receives warmer air from the single air flow due to the air flow being pre-heated through contact with the set of storage drives. Accordingly, in this scenario, the PSU may not receive adequate cooling. Further, conventional storage devices can experience a reverse airflow through the PSU because the larger storage device fans are stronger. Reverse flow can cause negative effects on the storage device such as diverting cooling air that could have cooled the storage devices. Also, in some instances, storage devices may experience times where the airflow through the PSU is somewhere between reverse flow and “normal” flow, causing the PSU to heat up quickly. For instance, the PSU may impede a percentage of the airflow due to the restrictive topography internal to the PSU enclosure. This reduces the cooling efficiency of the main air path.

The described technology addresses the deficiencies of a conventional storage device. The duct of the storage device enclosure of the described technology provides, to the PSU, a separate, dedicated flow of air. Providing the separate, dedicated airflow ensures a delivery of air to the PSU at substantially the ambient temperature of the air outside of the storage device. The conventional storage device that does not have the duct of the described technology, on the other hand, delivers air to the PSU that is warmer than this ambient temperature. For example, in the conventional storage device, the airflow that reaches the PSU is warmer than this ambient temperature because of previous contact of the airflow with other elements (e.g., storage devices) of the storage device or because of merging of the airflow with other air that is heated via contact with the other elements prior to reaching the PSU. Consequently, the storage device including the duct according to the described technology may enable a greater degree of cooling or a faster cooling of the PSU over the conventional storage device in situations where the PSU requires a greater cooling compared to the other components of the storage device. For example, if (A) the temperature of the PSU of the storage device is three degrees greater than a predetermined PSU maximum threshold temperature that ensures best performance of the PSU and (B) the temperature of the one or more storage drives of the storage device are two degrees greater than a predetermined storage drive maximum threshold temperature to ensure best functioning of the storage drives, then (C) the storage device of the described technology is able to provide a faster cooling of the PSU via the separate, dedicated airflow of the duct that does not contact the one or more storage drives, which is not providable by the conventional storage device that does not have this separate dedicated airflow. In another example, the temperature of the PSU is greater than the predetermined PSU maximum threshold temperature and the temperature of the storage drives is not greater than the predetermined storage device maximum threshold temperature. In this example, the storage device of the described technology may increase a speed of a fan that is dedicated to driving the dedicated airflow along the duct to the PSU without having to increase the speed of fans that drive airflow to the storage drives. Further, providing the separate, dedicated air flow for the PSUs of the described technology reduces the likelihood of occurrence of a reverse flow through the PSU compared to the likelihood of reverse air flow in conventional storage devices that do not have a separate, dedicated air flow for PSUs.

In the following description, reference is made to the accompanying drawings that form a part hereof and which is shown by way of illustration of at least one specific implementation. The following description provides additional specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples, including the figures, provided below. In some instances, a reference numeral may have an associated sub-label consisting of a lower-case letter to denote one of multiple similar components. When reference is made to a reference numeral without specification of a sub-label, the reference is intended to refer to all such multiple similar components.

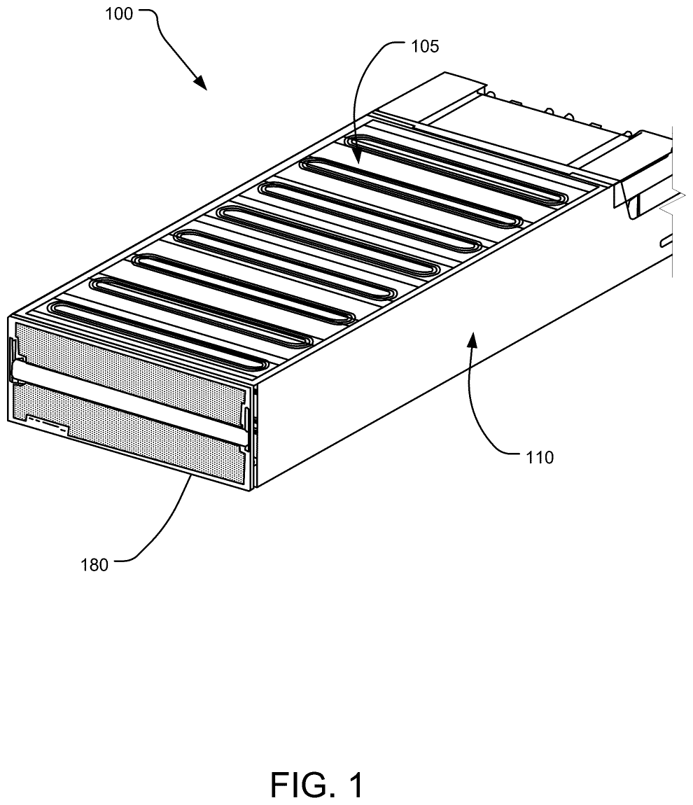

FIG. 1 depicts a storage device 100. The storage device 100 includes a storage drives section 180 that includes a set of storage drives. Storage drives may include hard disk drives (“HDDs”) and/or other storage devices. The storage drives section 180 is surrounded by an enclosure 110 and a cover 105. The enclosure 110 (e.g., a chassis) may be a housing designed to contain and protect, along with the cover 105, the storage drives of the storage drives section 180 from damage. The storage device 100 may include other components that are not labeled in FIG. 1. For example, the storage device 100 includes one or more fans (e.g. at the rear of the storage device 100) that provide airflow that goes around, through, in, or that otherwise contacts components (e.g., PSUs, storage drives) of the storage device 100. For example, the storage device 100 includes PSUs that provide power to one or more power-consuming elements of the storage device 100, for example, to storage drives of the storage drives section 180 and/or to one or more fans of the storage device 100. For example, a PSU may be a hardware device that converts alternating current (AC) electricity into direct current (DC) electricity and then distributes the DC electricity to one or more components of the storage device 100.

The enclosure 110 surrounds the storage drives section 180 and other components of the storage device 100. In some implementations, the enclosure 110 is rectangular-prism shaped, having a bottom surface (not visible in FIG. 1) and three side walls (two of which are visible in FIG. 1). The shape and configuration of the enclosure depicted in FIG. 1 is an example and other shapes/configurations may be used.

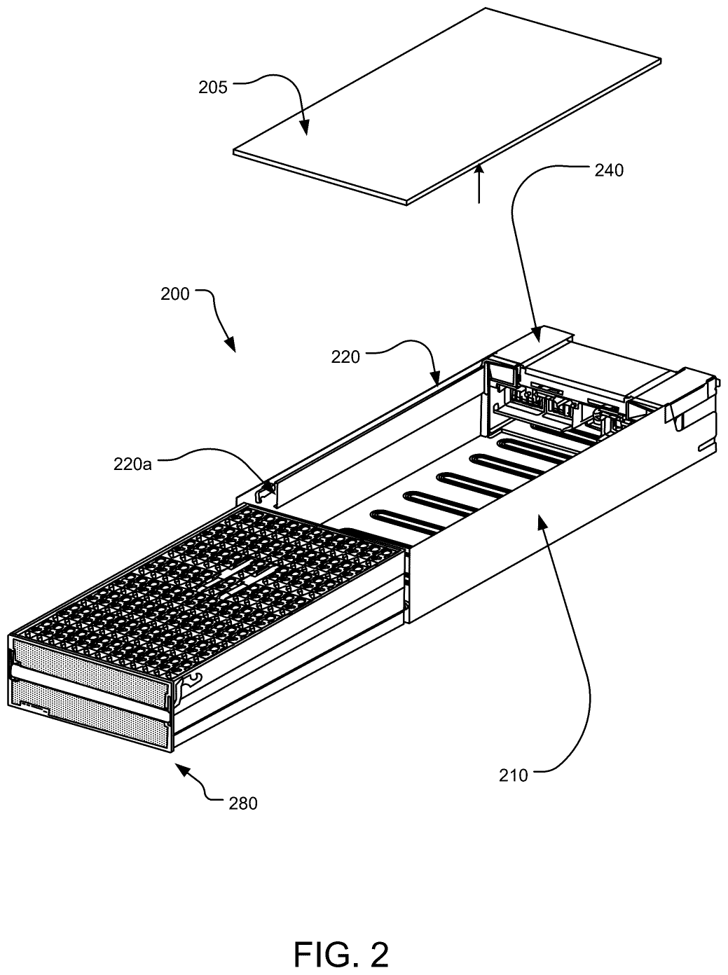

FIG. 2 depicts a storage device 200 with a storage drives section 280 retracted and a cover 205 removed from an enclosure 210. The enclosure 210 includes a bottom surface and three side walls. The enclosure 210 is connectable to the storage drives section 280 to at least partly enclose the storage drives section 280, for example, through sliding the storage drives section 280 into the enclosure 210. Connection through sliding is one example but other mechanisms for the enclosure 210 to cover (e.g., encase) the storage drives section 280 may be implemented. As depicted in FIG. 2, the enclosure 210 includes a duct 220 with an inlet 220a that runs along a side wall of the enclosure 210 from a front of the enclosure toward the back of the enclosure. For example, the plurality of storage drives of the storage drives section 280 are configured along a length of the enclosure 210 from a front of the of the enclosure 210 to a rear of the enclosure 210, as depicted in FIG. 2.

In some implementations, both side walls of the enclosure 210 include a respective duct 220 that includes a respective inlet 220a. Although not depicted in FIG. 2, in some implementations a top wall, a bottom wall, and/or other surface including a duct that runs along the respective top, bottom, and/or other surface of the enclosure 210 from a front of the enclosure toward the back of the enclosure 210. In some implementations, the inlet 220a is formed via contact of an duct section that is attached to the enclosure 210 along the side of the enclosure to form the hollow duct 220 between the duct section and the enclosure 210, as depicted in FIG. 2. In some implementations, the duct section fully encompasses the duct 220 (e.g., the duct section is a tube or other hollow piece fully enclosing the duct 220 that runs through the duct section) and the duct section is attached to or otherwise runs along the enclosure 210. In some implementations, the enclosure 210 itself encompasses the inlet 220a (e.g., a side wall, top wall, or bottom wall of the enclosure is hollow forming the inlet 220a. In other words one or more portions of the enclosure itself acts as a duct).

The duct 220 is configured to communicate (e.g., provide a channel/conduit for or otherwise direct) an airflow received at the front of the enclosure to a PSU 240 located toward the back of the enclosure. The inlet 220a of the duct 220 is depicted in FIG. 2 and the back of the duct 220 is not visible in the view depicted in FIG. 2. After reaching the PSU 240, the airflow continues into the PSU 240 (e.g., between the PSU and the enclosure 210) to a fan (not visible) located behind the PSU 240 and out of the back of the enclosure 210.

The airflow through the duct 220 is driven, in some implementations, by the fan (not visible) that is encompassed by the enclosure 210 at a rear of the enclosure 210 behind the PSU 240. For example, the enclosure 210 includes an opening at a back wall at a location of a fan such that air can pass through the duct 220, come into contact with the PSU 240 as it goes into the PSU 240 and between the PSU 240 and the enclosure 210, through the fan behind the PSU 240, and outside of the opening in the enclosure 210. However, in some implementations, the airflow proceeds from the back of the enclosure 210 through the fan, into the PSU 240, through the duct 220 and out the front of the enclosure 210 In certain implementations, duct 220 airflow is provided through the inlet 220a using the fan (not visible) and a separate airflow is provided through a storage drives section 280 by storage drives section fans (not visible). The storage drives section 280 airflow does not mix with or otherwise contact the inlet 220a airflow that passes through the duct 220 and into the PSU 240.

In the example depicted in FIG. 2, a fan (e.g., a PSU fan unit, which is not visible in FIG. 2) is located at the back of the enclosure. However, in some implementations, the fan may be located at a front of the enclosure or at some point along the duct 220 (e.g., a first portion of the duct 220 reaches the fan and a second portion of the duct 220 proceeds from the fan until it reaches the PSU 240 and opening of the enclosure 210. For example, the fan may be located anywhere along a path of the air flow that generated through the duct 220.

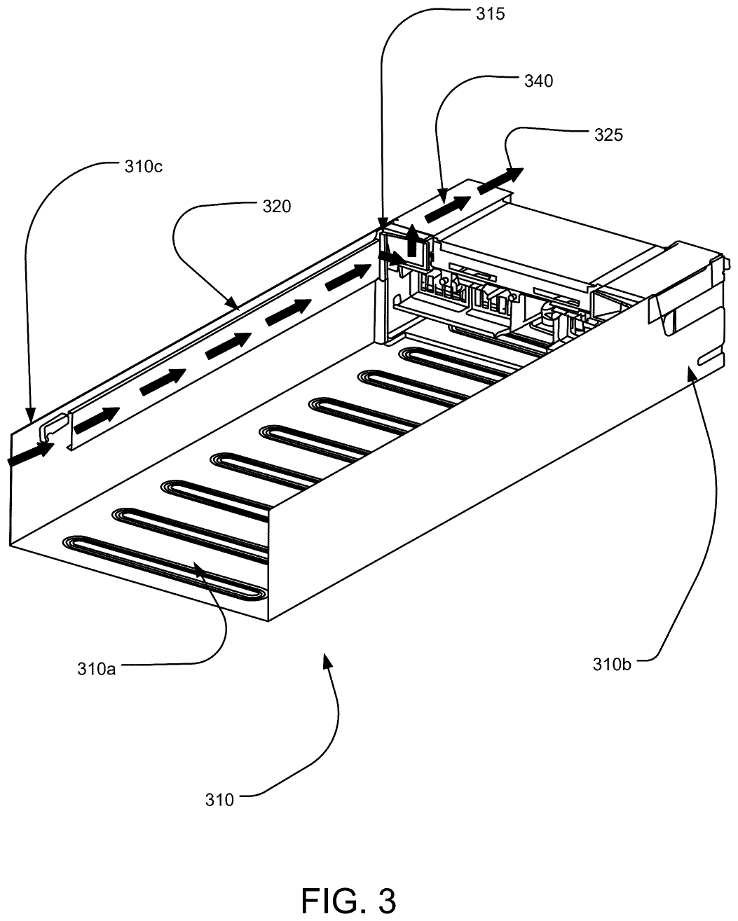

FIG. 3 depicts an example enclosure 310 that is configured to at least partly enclose a storage drives section of a storage device. The enclosure 310 includes a bottom surface 310a, a side wall 310b, a side wall 310c, and a rear wall (not visible). The example enclosure 310 includes a duct 320 that runs along a side wall of the enclosure 310 from a front of the enclosure 310 toward the back of the enclosure 310 such that an airflow path 325 passing through the duct 320 and redirected through a connecting plenum 315 and comes into contact with and goes into a PSU 340 and then out a back wall (not visible) of the enclosure 310. A fan (not visible) at the rear of the enclosure behind the PSU 340 drives the airflow from the front of the duct 320, through the duct 320 and the plenum 315, into the PSU 340, and out the rear wall of the enclosure 310.

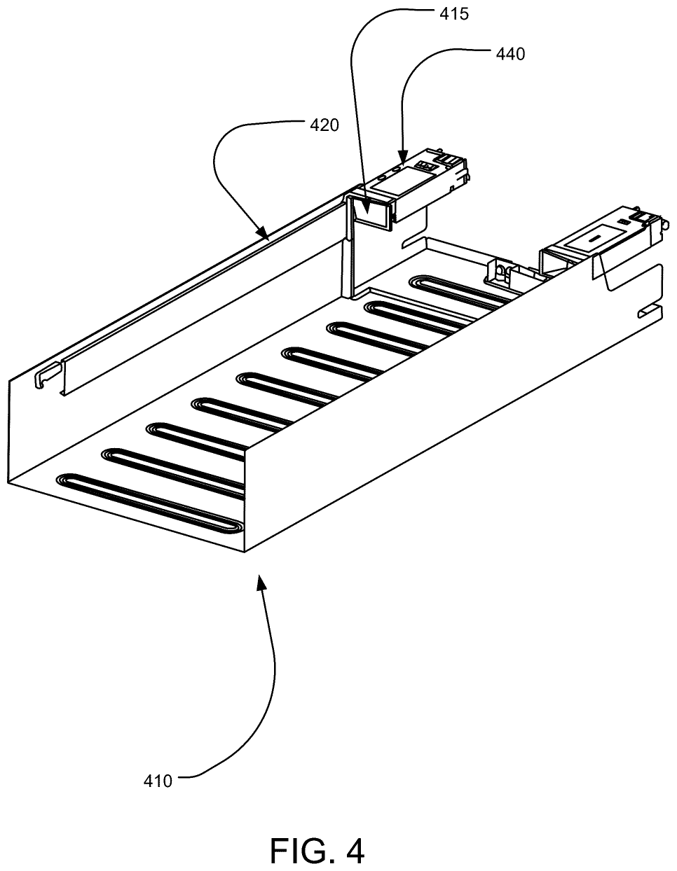

FIG. 4 depicts a portion of an example enclosure 410 that is configured to at least partly enclose a storage drives section of a storage device. The enclosure 410 includes a bottom surface, a side wall, a side wall, and a rear wall (not depicted). The example enclosure 410 includes ducts (e.g. duct 420 and a second duct that is not visible) that run along side walls of the enclosure 410 from a front of the enclosure 410 toward the back of the enclosure 410 such that an airflow passing through each duct (e.g. duct 420) comes into contact with and goes into a PSU (e.g., PSU 440) and then out a back wall (not depicted) of the enclosure 410. A fan (not visible) at the rear of the enclosure behind the PSU 440 drives the airflow from the front of the duct 420, through the duct 420, into the PSU 440, and out the rear wall of the enclosure 410.

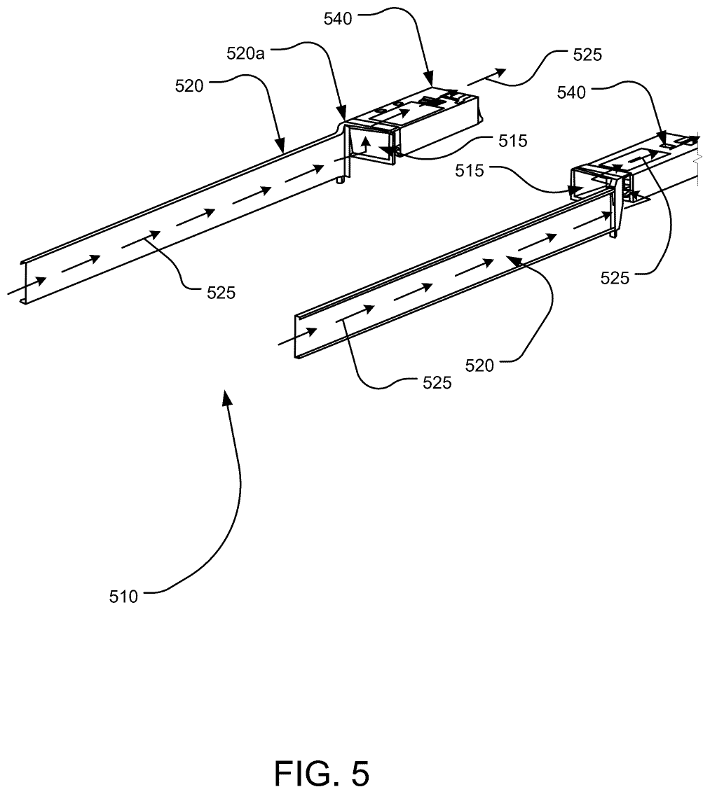

FIG. 5 depicts a portion of an example enclosure 510 including ducts 520 connecting plenums 515 and PSUs 540. As depicted in FIG. 5, each duct 520 may widen at cavity 520a in connecting plenum 515 as it flows through the path 525 through its respective PSU 540. The air expands in the cavity 520a as it passes through plenum 515, increasing an amount of air that is able to contact the PSU 540 for improved cooling of the PSU 540. In some implementations, inclusion of the cavity 520a re-directs the airflow from a vertical rectangular opening to a horizontal rectangular opening to rotate the airflow.

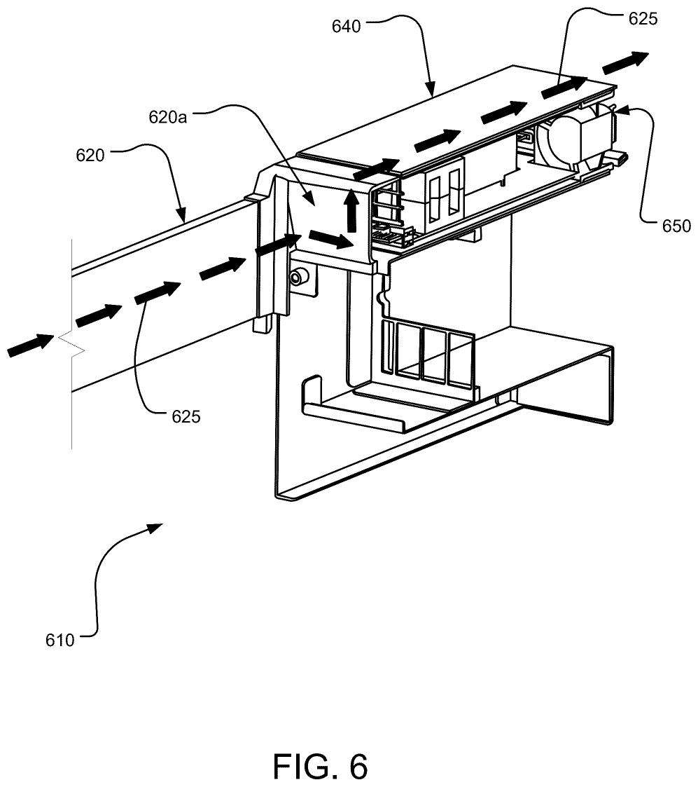

FIG. 6 depicts a portion of an example enclosure 610 including a duct 620. As depicted in FIG. 6, the duct 620 widens at air expansion cavity 620a as it passes through a PSU 640. The air expansion cavity 620a of the duct 620 increases an amount of air that is able to contact the PSU 640 for improved cooling of the PSU 640. The fan 650 at the rear of the enclosure behind the PSU 640 drives the airflow from the front of the duct 620, through the duct 620, into the PSU 640, and out the rear wall of the enclosure 610.

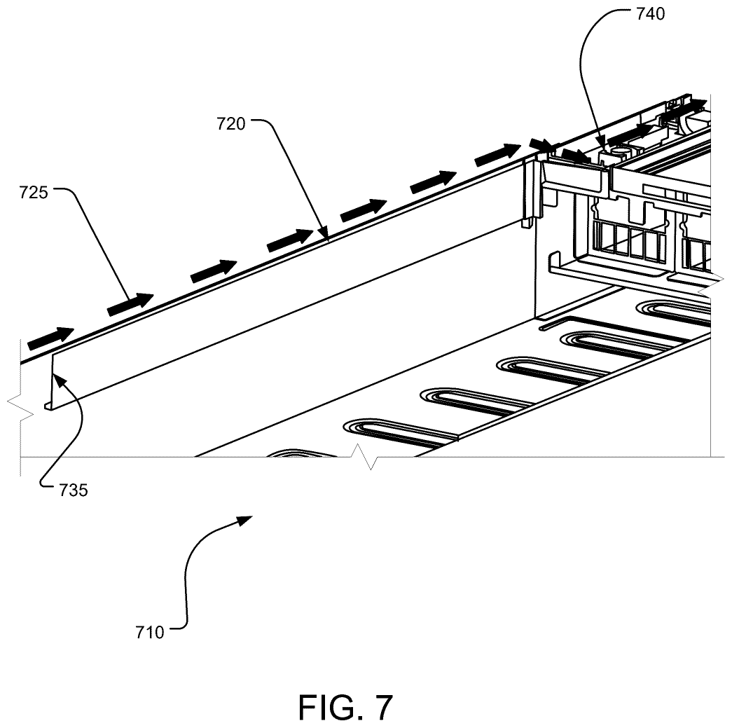

FIG. 7 depicts a portion of an example enclosure 710 including a duct 720. In the example enclosure 710, the duct 720 is formed from an inlet portion 735 (e.g., a duct portion) that is attached to a side wall of the enclosure 710 such that the duct 720 is formed as a space between the inlet portion 735 and the side wall. Other implementations for forming the duct 720 (e.g., a hollow tube or piece that fully encompasses the duct 720 is attached to the side wall, the side wall itself is hollow, etc.) may be used instead, as described herein. The duct 720 communicates the airflow 725 from the front of the duct 720, through the duct 720, into the PSU 740, and out the rear wall of the enclosure 710.

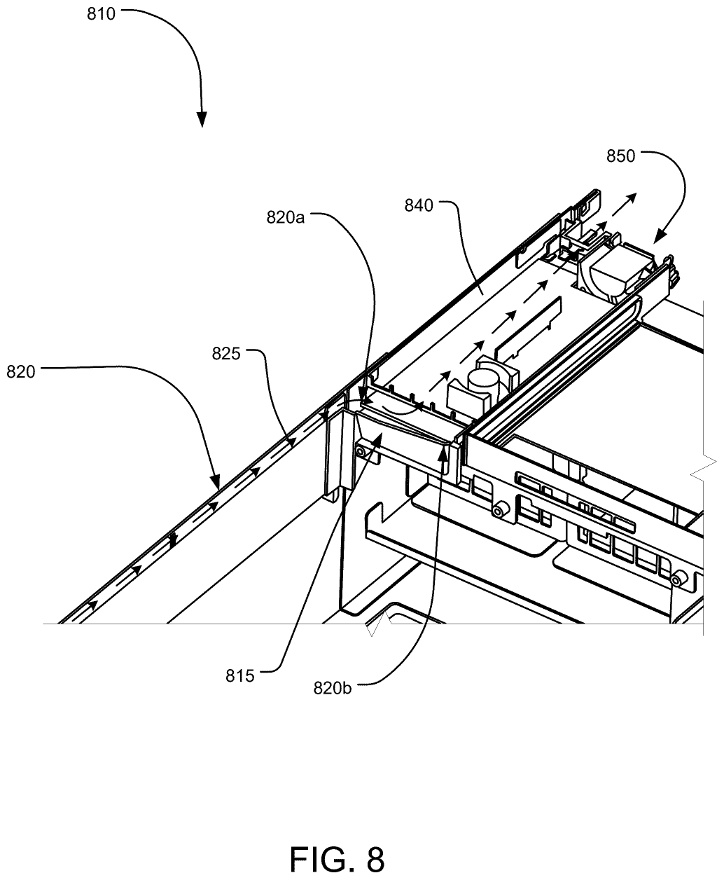

FIG. 8 depicts a portion of an example enclosure 810 including a duct 820 with air expansion cavities for effective cooling of a PSU. The duct 820 connects to the plenum 815 that widens at air expansion cavities 820a and 820b as it passes into a PSU 840. The air expansion cavities 820a and 820b of the plenum 815 increase the amount of air that is able to contact the PSU 840 for improved cooling of the PSU 840. For example, the plenum 815 widens between the duct 820 wall alongside the PSU 840 at air expansion cavity 820a. Air expansion cavity 820b extends in front of the PSU 840 (e.g., in a plane perpendicular to the length of the enclosure 810) and enables the airflow to additionally contact the front of the PSU 840 to enable increased cooling effect from the airflow. The fan 850 at the rear of the enclosure behind the PSU 840 drives the airflow 825 from the front of the duct 820, through the duct 820, through the plenum 815 and into the PSU 840, and out the rear wall of the enclosure 810. In some implementations, the fan 850 (e.g., PSU fan unit) is located on a side of the PSU 840 that is opposite the air expansion cavity 820b.

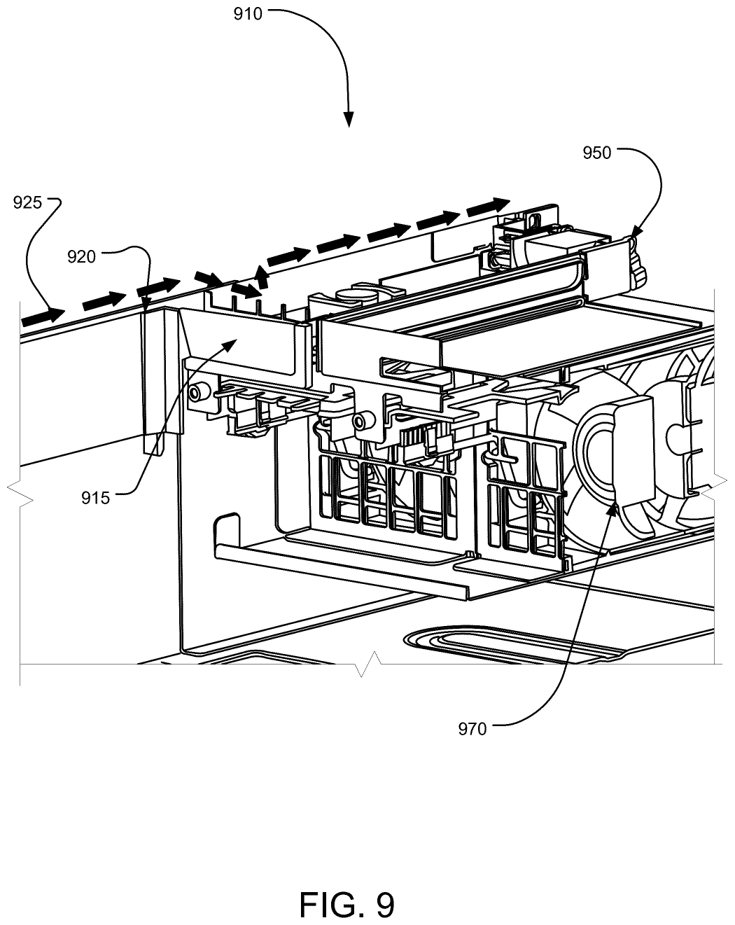

FIG. 9 depicts a portion of an example enclosure 910 including a duct 920 for cooling of a PSU 940. A fan 950 at the rear of the enclosure 910 behind the PSU 940 drives the airflow 925 from the front of the duct 920 (not visible), through the duct 920, through the plenum 915 and into the PSU 940, and out the rear wall of the enclosure 910. In some implementations, a separate set of storage drives section fans (e.g., storage drives section fan 970) drive an airflow (e.g., push, pull, or otherwise force air) through the storage drives section (not depicted) and out the rear wall (not visible) of the enclosure 910.

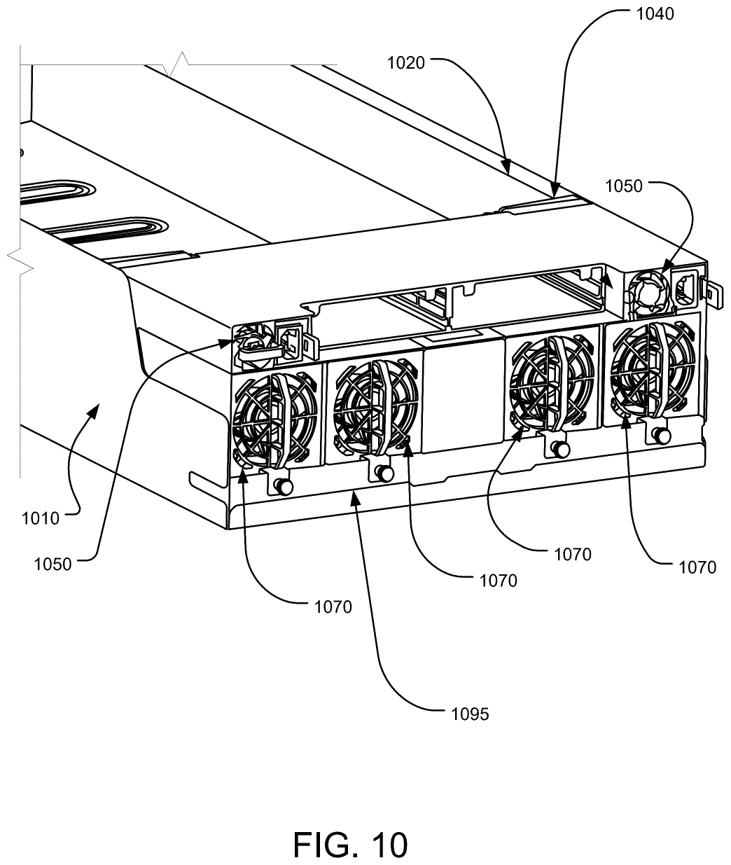

FIG. 10 depicts a portion of an example enclosure 1010 including a duct 1020 for cooling of a PSU. A fan 1050 at the rear wall 1095 of the enclosure behind the PSU 1040 drives the airflow from the front of the duct 1020 (not visible), through the duct 1020, into the PSU 1040, and out the rear wall of the enclosure 1010. In some implementations, a separate set of storage drives section fans 1070 drive an airflow through the storage drives section (behind the storage drives section fans 1070 depicted in FIG. 10 but not visible in FIG. 10) and out the rear wall 1095 of the enclosure 1010. The airflow that passes through the storage drives section does not mix with or come into contact with the airflow that passes through the duct 1020 and the PSU 1040.

Unless otherwise indicated, all numbers expressing feature sizes, amounts, and physical properties are to be understood as being modified by the term “about,” whether or not the term “about” is immediately present. Accordingly, unless indicated to the contrary, any numerical parameters set forth are approximations that can vary depending upon the desired properties sought to be obtained by those skilled in the art utilizing the teachings disclosed herein.

As used herein, the singular forms “a,” “an,” and “the” encompass implementations having plural referents, unless the content clearly dictates otherwise. As used in this specification and the appended claims, the term “or” is generally employed in its sense including “and/or” unless the content clearly dictates otherwise.

Spatially related terms, including but not limited to, “bottom,” “lower”, “top”, “upper”, “beneath”, “below”, “above”, “on top”, “on,” etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

Since many implementations of the invention can be made without departing from the spirit and scope of the invention, the invention resides in the claims hereinafter appended. Furthermore, structural features of the different implementations may be combined in yet another implementation without departing from the recited claims.

What is claimed is:

1. A device, comprising:
an enclosure;
a plurality of storage drives configured along a length of the enclosure from a front of the enclosure to a rear of the enclosure, the enclosure surrounding the plurality of storage drives at least in part; and
a duct configured along the length of the enclosure, the duct configured to communicate an airflow from the front of the device to a power supply unit (PSU) located near a rear of the device.

2. The device of claim 1, the duct comprising an air expansion cavity configured to expand the airflow to a surface of the PSU.

3. The device of claim 2, wherein the air expansion cavity is configured on a side of the PSU opposite a side with a PSU fan unit.

4. The device of claim 2, wherein the air expansion cavity is further configured to communicate the airflow below the PSU towards a PSU fan unit.

5. The device of claim 2, wherein the air expansion cavity is further configured to communicate the airflow above the PSU towards a PSU fan unit.

6. The device of claim 2, wherein the air expansion cavity is configured in a plane perpendicular to a length of the enclosure.

7. The device of claim 1, wherein the airflow does not mix or contact with another airflow provided to the plurality of storage drives.

8. The device of claim 1, wherein the duct is configured along an outer surface of the enclosure.

9. The device of claim 1, further comprising a PSU fan unit configured in the enclosure to drive the airflow by forcing air through the duct.

10. The device of claim 9, wherein the PSU fan unit is configured behind the PSU at the rear of the enclosure.

11. A storage system, comprising:
an enclosure;
a plurality of storage drives configured along a length of the enclosure from a front of the enclosure to a rear of the enclosure, the enclosure surrounding the plurality of storage drives at least in part;
a duct configured along the length of the enclosure, the duct configured to communicate an airflow from the front of the enclosure to a power supply unit (PSU) located near a rear of the enclosure;
a PSU fan unit configured to drive the airflow; and
an air expansion cavity configured within the duct to expand the airflow to a surface of the PSU.

12. The storage system of claim 11, wherein the air expansion cavity is configured on a side of the PSU opposite a side with a PSU fan unit.

13. The storage system of claim 11, wherein the air expansion cavity is further configured to communicate the airflow below the PSU towards a PSU fan unit.

14. The storage system of claim 11, wherein the air expansion cavity is further configured to communicate the airflow above the PSU towards a PSU fan unit.

15. The storage system of claim 11, wherein the air expansion cavity is configured in a plane perpendicular to a length of the enclosure.

16. The storage system of claim 11, wherein the airflow does not mix or contact with another airflow provided to the plurality of storage drives.

17. The storage system of claim 11, wherein the duct is configured along a side surface of the enclosure.

18. The storage system of claim 11, wherein the duct is configured along a top surface or a bottom surface of the enclosure.

19. The storage system of claim 11, wherein the PSU fan unit is configured in the duct in front of the PSU.

20. The storage system of claim 11, wherein the PSU fan unit is configured behind the PSU at the rear of the enclosure.
